(19) United States
(12) Patent Application Publication
(10) Pub. No.: US 2025/0240931 A1
(43) Pub. Date: Jul. 24, 2025

(54) INTEGRATED DATA CENTER ABSORPTION SYSTEM

(71) Applicant: Advanced Liquid Cooling Technologies Inc., Anderson, SC (US)

(72) Inventors: Nan Chen, Anderson, SC (US); Yunshui Chen, Greer, SC (US)

(21) Appl. No.: 19/024,984

(22) Filed: Jan. 16, 2025

Related U.S. Application Data
(60) Provisional application No. 63/622,842, filed on Jan. 19, 2024.

(51) Int. Cl. H05K 7/20

(52) U.S. Cl. CPC H05K 7/20827

(57) ABSTRACT

A multi-stage absorption chiller may include one or more of a plurality of absorber/generator stages, each stage configured to absorb cooled vapor by a concentrated solution to create a diluted solution and heat the diluted solution to produce a vapor refrigerant and the concentrated solution, a condenser, configured to condense the vapor refrigerant to a cooled high pressure liquid, a pressure regulator, configured to regulate the cooled high pressure liquid from the condenser to a low pressure mixture of liquid and vapor, and an evaporator, configured to cool and evaporate the vapor from the low pressure mixture of liquid and vapor and provide the cooled vapor to the plurality of absorber/generator stages.

### PRIORITY

This patent application claims priority from Provisional U.S. Patent Application No. 63/622,842, filed Jan. 19, 2024, entitled INTEGRATED ABSORPTION SYSTEM DRIVEN BY THE HEAT FROM THE DATA CENTER (DC) and naming Nan Chen, He Zhao, and Yunshui Chen as the inventors, the disclosure of which is incorporated herein in its entirety, by reference.

### FIELD

Illustrative embodiments of the invention generally relate to data center server cooling and, more particularly, various embodiments of the invention relate to a multi-stage absorption system for efficient data center cooling.

### BACKGROUND

Data centers may include large numbers of computers, data storage, and networking resources. The computers are typically servers, each including one or more very powerful processors and significant memory resources. The servers consume significant amounts of power and produce a large amount of heat, which must be dealt with by the data center.

Data center cooling maintains the right temperatures for servers and associated equipment to prevent overheating and server shutdown and ensure reliable and efficient performance. Formerly, data centers used various forms of air cooling and refrigeration to maintain proper equipment temperatures. However, with dramatic increases in processor and computer operating speeds, traditional air cooling is insufficient. Newer systems use various forms of liquid or oil cooling to maintain equipment temperatures.

### SUMMARY OF VARIOUS EMBODIMENTS

In accordance with one embodiment of the invention, a multi-stage absorption chiller may include one or more of a plurality of absorber/generator stages, each stage configured to absorb cooled vapor by a concentrated solution to create a diluted solution and heat the diluted solution to produce a vapor refrigerant and the concentrated solution. The chiller also has a condenser configured to condense the vapor refrigerant to a cooled high pressure liquid, a pressure regulator configured to regulate the cooled high pressure liquid from the condenser to a low pressure mixture of liquid and vapor, and an evaporator configured to cool and evaporate the vapor from the low pressure mixture of liquid and vapor and provide the cooled vapor to the plurality of absorber/generator stages.

In accordance with other embodiments, the plurality of absorber/generator stages may include a low absorber, configured to absorb a low pressure cooled vapor by a first concentrated solution to create a first diluted solution, a low generator, configured to heat the first diluted solution from the low absorber to produce an intermediate pressure vapor refrigerant and the first concentrated solution to the low absorber, a high absorber, configured to absorb the intermediate pressure vapor refrigerant from the low generator by a second concentrated solution to create a second diluted solution, and a high generator, configured to heat the second diluted solution from the high absorber to produce a high pressure vapor refrigerant and the second concentrated solution to the high absorber.

In accordance with other embodiments, the plurality of absorber/generator stages may include an intermediate absorber, configured to absorb the intermediate pressure vapor refrigerant from the low generator by a second concentrated solution to create a second diluted solution and an intermediate generator, configured to heat the second diluted solution from the intermediate absorber to produce a high pressure vapor refrigerant and the second concentrated solution to the intermediate absorber. The high absorber is instead configured to absorb the high pressure vapor refrigerant from the intermediate generator by a third concentrated solution to create a third diluted solution and heat the third diluted solution from the high absorber to produce a high pressure vapor refrigerant and the third concentrated solution to the high absorber.

In accordance with other embodiments, the low generator and the high generator heat the first diluted solution and the second diluted solution, respectively, from a heated concentrated coolant from a data center and supply cooled concentrated coolant to the data center.

In accordance with other embodiments, the multi-stage absorption chiller may include a low pump, configured to pump the first diluted solution from the low absorber to the low generator and a high pump, configured to pump the second diluted solution from the high absorber to the high generator.

In accordance with other embodiments, the multi-stage absorption chiller may include a low heat exchanger, configured to transfer heat from the first concentrated solution to the first diluted solution and a high heat exchanger, configured to transfer heat from the second concentrated solution to the second diluted solution.

In accordance with other embodiments, the multi-stage absorption chiller may include a heat rejector, configured to cool the cooling fluid from the condenser and provide cooled cooling fluid to at least a low absorber and a high absorber of the plurality of absorber/generator stages. At least the low absorber and the high absorber are configured to supply heated cooling fluid to the condenser.

In accordance with other embodiments, the intermediate temperature may track the high temperature.

In accordance with other embodiments, a three-stage absorption chiller may include a low absorber, configured to absorb low pressure cooled vapor by a first concentrated solution to create a first diluted solution, a low generator, configured to heat the first diluted solution from the low absorber to produce an intermediate pressure refrigerated vapor and the first concentrated solution to the low absorber, an intermediate absorber, configured to absorb intermediate pressure cooled vapor by a second concentrated solution to create a second diluted solution, and an intermediate generator, configured to heat the second diluted solution from the intermediate absorber to produce a high pressure refrigerated vapor and the second concentrated solution to the intermediate absorber, a high absorber, configured to absorb the high pressure refrigerated vapor from the intermediate generator by a third concentrated solution to create a third diluted solution, a high generator, configured to heat the third diluted solution from the high absorber to produce a high pressure vapor refrigerant and the third concentrated solution to the high absorber, a condenser, configured to condense the high pressure vapor refrigerant from the high generator to a cooled high pressure liquid, a pressure regulator, configured to regulate the cooled high pressure liquid from the condenser to a low pressure mixture of liquid and vapor, and an evaporator, configured to cool and evaporate the vapor from the low pressure mixture of liquid and vapor and provide the low pressure cooled vapor to the low absorber.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a block diagram of a data center cooling system in accordance with illustrative embodiments of the invention.

FIG. 2 schematically shows a block diagram of an absorption chiller in accordance with illustrative embodiments of the invention.

FIG. 3A schematically shows a coolant temperature range diagram for a single-stage absorption chiller in accordance with embodiments of the invention.

FIG. 3B schematically shows a coolant temperature range diagram for a dual-stage absorption chiller in accordance with embodiments of the invention.

FIG. 4 schematically shows a block diagram of a dual-stage absorption chiller in accordance with a first embodiment of the invention.

FIG. 5 schematically shows a block diagram of a dual-stage absorption chiller in accordance with a second embodiment of the invention.

FIG. 6 schematically shows a block diagram of a three-stage absorption chiller in accordance with a third embodiment of the invention.

### DESCRIPTION OF ILLUSTRATIVE EMBODIMENTS

In illustrative embodiments, a multi-stage absorption chiller for cooling servers and other components in a data center is described. Multi-stage absorption chillers include a condenser, an evaporator, two or more absorbers, and two or more generators, in addition to other components.

Absorption chillers/heaters use high-temperature heat as their main energy source, A very small amount of electricity is needed in absorption systems compared with compression cycle systems, because only the pumps are operated by electricity, Absorption chillers can be used for both heating and cooling purposes simultaneously, by processing cooling water from the corresponding absorber and the condenser.

Simple absorption systems are one-stage systems having one absorber and one generator. Benefits include lower investment costs, but the tradeoff is lower efficiency. The use of multistage absorbers or generators increases the system performance. Absorption chillers commonly use water as a refrigerant and a solution of lithium bromide (LiBr) as the absorbent. The LiBr concentration, for example, is typically around 64% after the generator and approximately 60% after the absorber. Details of various embodiments are discussed below.

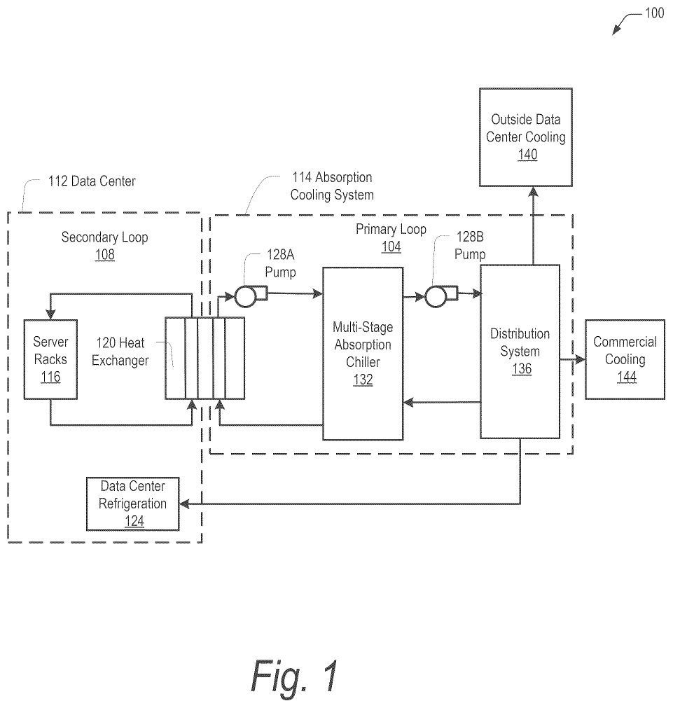

FIG. 1 schematically shows a block diagram of a data center cooling system 100 in accordance with illustrative embodiments of the invention. As shown in FIG. 1, the data center cooling system 100 of a data center 112 includes an absorption cooling system 114. The data center 112 generally includes many server computers organized into groups of racks 116. Each rack 116 may include any number of computers, but typically 10-30 identical computers in a “blade” format that may be individually added to or removed from a rack 116. Each rack 116 often includes an associated cooling system to cool very high temperature electronic components, such as central processing units (CPUs) and/or graphical processing units (GPUs). Each high-temperature component may have an associated heat sink that is cooled by air, a liquid, or a combination of air and a liquid. Older servers and components produced much less heat than modern components, so air cooling was often sufficient. However, present day individual components may produce over 500 watts of heat, requiring more advanced liquid cooling systems. Illustrative embodiments address this problem with an advanced liquid cooling system for data center applications.

The data center cooling system 100 may include a primary cooling loop 104 in the absorption cooling system 114, and a secondary cooling loop 108 in the data center 112. The primary cooling loop 104 is outside the data center and includes the main cooling components for the system 100. The secondary cooling loop 108 is generally within the data center 112 and performs primary heat extraction from the server racks 116 and return of cooled liquids to the server racks 116. The primary cooling loop 104 is separated from the secondary cooling loop 108 by a heat exchanger 120 or a thermal storage tank. The heat exchanger 120 includes primary loop 104 piping in close proximity to secondary loop 108 piping. Liquids traveling in the primary loop 104 preferably are never in direct contact with liquids in the secondary loop 108. Pipes of the secondary loop 108 carrying very hot liquids transfer a portion of the heat to pipes of the primary loop 104 in the heat exchanger 120. A pump 128 adds velocity to the primary loop 104 liquid and passes the primary loop 104 liquid to a multi-stage absorption chiller 132.

The multi-stage absorption chiller 132 returns cooled liquid to the heat exchanger 120 within the primary loop 104, where the cooled liquid picks up heat from the secondary loop 108 and repeats the process by pumping the heated liquid back to the multi-stage absorption chiller 132.

In addition to providing a cooling function for the secondary loop 108, the multi-stage absorption chiller 132 also may provide cooled liquid through a pump 128B to a distribution system 136. The distribution system 136 may provide a refrigerant to data center refrigeration 124 for air conditioning within the data center 112. The distribution system 136 may also provide commercial cooling 144 to office buildings, warehouses, and the like. Finally, the distribution system 136 may provide outside data center cooling 140, such as cooling for a school, hospital, market, apartment, or a central cooling station for a community.

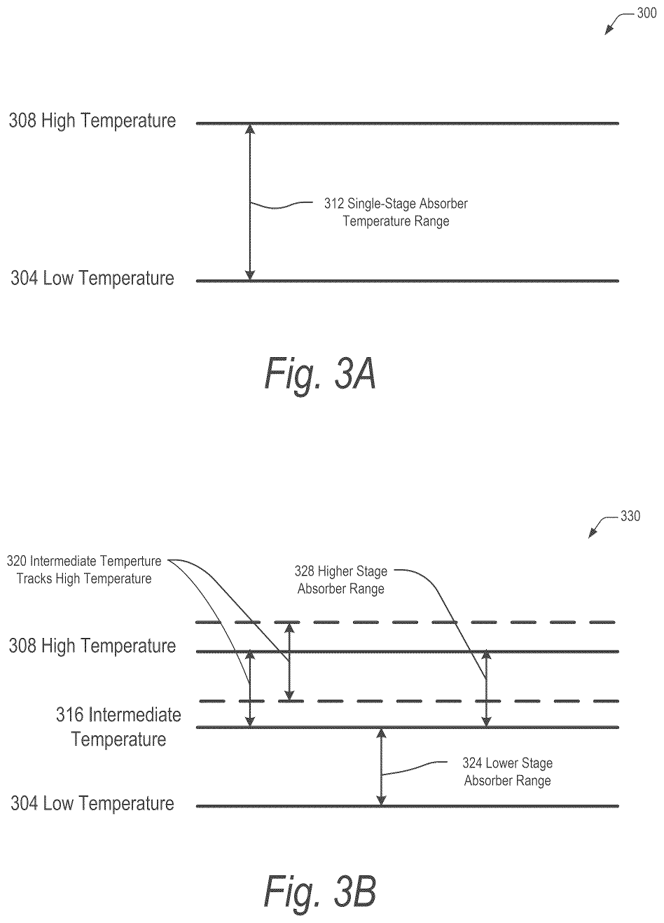

The multi-stage absorption chiller 132 provides a highly efficient data center 112 cooling system that does not require a heater. Single-stage conventional absorption chillers 200 are less efficient and require a heater. For example, a heater may be necessary between the heat exchanger 120 primary loop output and the pump 128A or between the pump 128A and a single stage absorption chiller 200. The heater is required to add heat to the hot liquid to create a minimum separation between the hot liquid and the cooled liquid. This is explained in more detail with respect to FIGS. 3A and 3B.

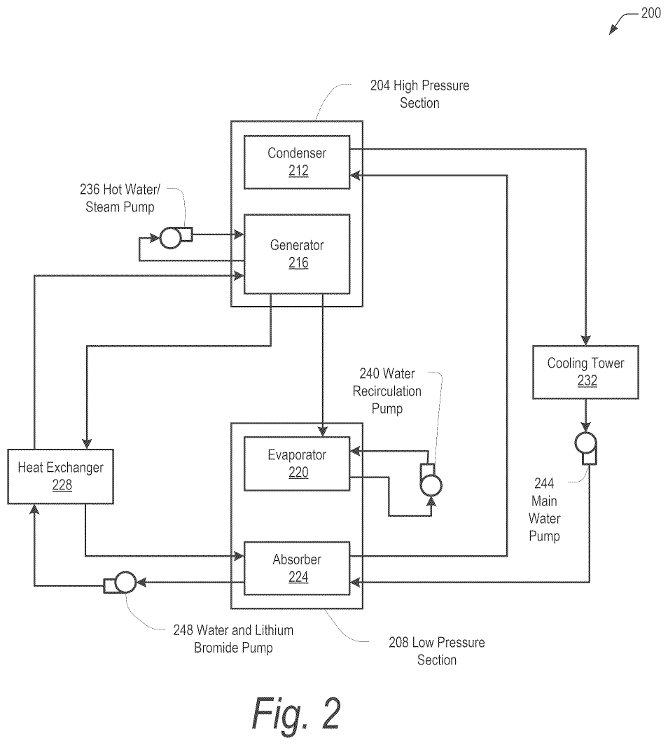

FIG. 2 schematically shows a block diagram of a single-stage absorption chiller 200 in accordance with illustrative embodiments of the invention. An absorption chiller s different than other chillers because it does not require a compressor. Instead, it uses heat to generate cooling.

Absorption chillers 200 do not use conventional refrigerants. Instead, in illustrative embodiments, they use water as a refrigerant mixed with either ammonia or Lithium Bromide. Lithium Bromide is more common because it is safer and non-toxic. Lithium Bromide is a salt in a liquid form that attracts moisture. Water and Lithium Bromide may be mixed together. When heated in a vessel, the water and Lithium Bromide separate. The water will rise and evaporate, and the Lithium Bromide will sink to the bottom of the vessel.

The absorption chiller 200 includes a condenser 212 and a generator 216, which are part of a high pressure section 204. An evaporator 220 and an absorber 224 are part of a low pressure section 208. There is also a heat exchanger 228 to improve the efficiency of the system. The high pressure section 204 operates at higher pressure than the low pressure section 208. In various embodiments, a mixture of approximately 50% Lithium Bromide and 40% water is pumped 248 from the absorber 224 through the heat exchanger 228, and then up into the generator 216. The generator 216 is partly filled to form a reservoir for the mixture of water and Lithium Bromide.

A source of heat (hot water/steam) flows through a pipe within the reservoir of the generator 216, which causes the Lithium Bromide and water solution to separate. The water will evaporate as vapor and rise into the condenser section 212 leaving the Lithium Bromide behind.

The Lithium Bromide builds up and sinks to the bottom of the high pressure section 204 due to the weight of the molecules. This causes a concentration of Lithium Bromide liquid at the base of the generator 216 and this will then flow down, through the heat exchanger 228, and be sprayed over the absorber 224, where it can mix with water molecules.

The water vapor condenses into a liquid as in comes into contact with a cooling coil in the condenser 212. Water from a cooling tower 232 passes through a sealed pipe within the condenser 212 to remove the heat of the water vapor which causes it to condense into a liquid form.

This liquid water is then collected in a tray within the condenser 212 and this will flow through a pipe down into the evaporator 220. The volume flow rate of water is controlled via a fixed orifice or opening at the bottom of the high pressure section 204. The evaporator 220 is at a very low pressure, near vacuum, which causes the water to flash and drop in temperature due to the rapid drop of pressure. The water reduces temperature to around 4° C. (40° F.).

The “chilled water” line runs through the evaporator 220, just like a typical air or water cooled chiller, and this carries all the unwanted heat of the data center etc. This passes through a cooling coil where the cold water from the condenser 212 is then sprayed over the surface to extract the unwanted thermal energy.

The “chilled water” will enter the evaporator coil 220 at around 12° C. (54° F.) and as the spray of the cold condenser water comes into contact with the tube of chilled water line, it will transfer its thermal energy out of the “chilled water” and into the “condenser water”. The chilled water does not mix with the condenser water because they are always separated by a pipe wall.

As the heat transfers through the pipe wall and into the condenser water, on the outside of the tubes, the condenser water evaporates into steam due to the low pressure of the chamber 208. As it evaporates it carries the unwanted thermal energy away with it. The chilled water circuit has now given up its heat and by the time it leaves the evaporator 220 it will be around 7° C. (45° F.) and is ready to be pumped around the data center to collect more heat.

Another loop will recirculate any water that missed the pipes and didn't boil. This will be pumped back to the top of the evaporator 220 and sprayed again until it all evaporates into steam.

The water vapor, or steam, produced by the evaporator 220 is then attracted and pulled towards the strong Lithium Bromide solution being sprayed in the absorber 224. This is similar to a magnetic force, where the attraction is strong enough that the water particles flow by themselves straight to the absorber 224 to be together with the Lithium Bromide. This attraction between the water particles and the Lithium Bromide particles is what causes the vacuum in the chamber 208. When the two fluids come in contact, they generate heat and this, as well as the heat collected from the chilled water loop, needs to be removed so that is why the cooling tower 232 water loop also passes through the absorber 224. The cooling tower 232 water also condenses the residual vapor particles back into a liquid. The mixture of Lithium Bromide and water collect at the bottom of the low pressure section 208 ready to be pumped back to the generator 216 again to repeat the cycle. In addition to the water and Lithium Bromide pump 248, the absorption chiller 200 may also include a hot water/steam pump 236 for the generator 216, a water recirculation pump 240 associated with the evaporator 220, and a main water pump 244 associated with the cooling tower 232.

FIG. 3A schematically shows a coolant temperature range diagram 300 for a single-stage absorption chiller 200 in accordance with embodiments of the invention.

A single stage absorption chiller 200 operates between a low coolant temperature 304 and a high coolant temperature 308. Coolant from the secondary loop 108 is heat exchanged with the primary loop 104 at the high temperature 308. The single-stage absorption chiller 200 cools the coolant to the low temperature 304 (e.g., 15 degrees Celsius) where the coolant is again heat exchanged with the secondary loop 108. In order to operate efficiently, single-stage absorption chillers 200 operate across a minimum single-stage absorber temperature range 312. In some cases, the high temperature coolant is not at the required high temperature 308 for efficient absorption chiller operation (i.e., the single-stage absorber temperature range 312 is insufficient, or too low. For example, the high temperature coolant received by the single-stage absorption chiller 200 may be 40 degrees Celsius and the single-stage absorption chiller 200 may require the high coolant temperature 308 to be over 50 degrees Celsius for efficient operation. In such cases, a heater may need to be installed in the high temperature coolant inlet to the single-stage absorption chiller 200. The heater may raise the coolant temperature by a fixed or variable amount to ensure the minimum single-stage absorption chiller temperature range 312 is achieved and maintained.

FIG. 3B schematically shows a coolant temperature range diagram 330 for a dual-stage absorption chiller in accordance with embodiments of the invention. Pressures and temperatures at a saturation state are uniquely correlated. A temperature at a given pressure may be determined using a pressure-temperature (P-T) diagram. Each fluid has its own distinct P-T diagram.

Additional stages may be added for other forms of multi-stage absorption chillers 132, but the dual stage absorption chiller is illustrated for simplicity. Unlike the single stage absorption chiller 200, dual-stage absorption chillers 132 incorporate an intermediate coolant temperature 316 between the low temperature 304 and the high temperature 308. A higher stage absorber range 328 cools the coolant from the high temperature 308 to the intermediate temperature 316. A lower stage absorber range 324 cools the coolant from the intermediate temperature 316 to the lower temperature 304. The dual stage absorption chiller (or other forms of multi-stage absorption chillers 132) can operate efficiently across reduced temperature ranges compared to single-stage absorption chillers 200 and beneficially do not require heaters, saving cost and complexity. In the dual-stage absorption chiller, the intermediate temperature tracks the high temperature 320 such that the temperature difference between the high temperature 308 and the intermediate temperature 316 remains essentially fixed.

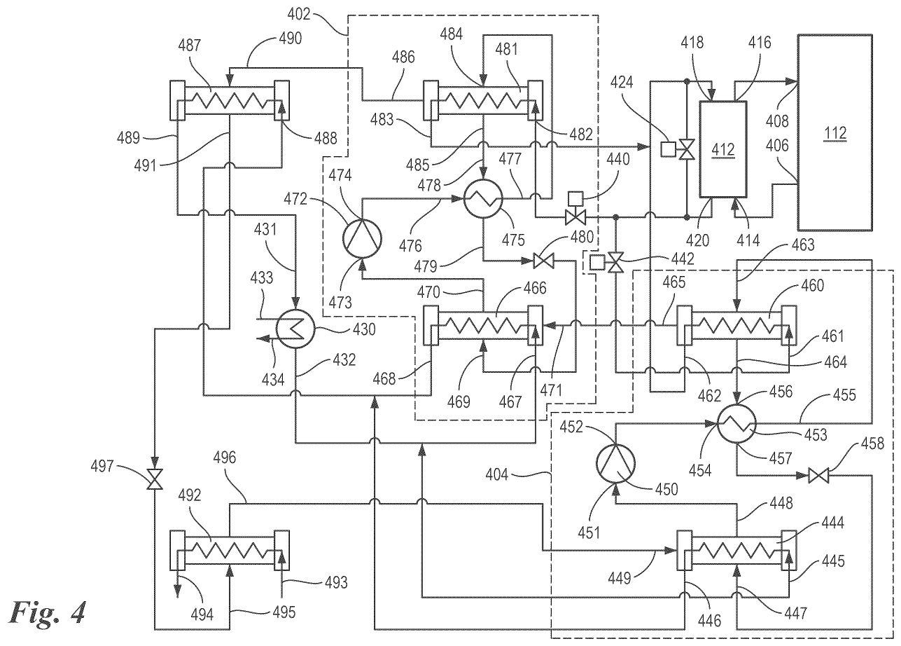

FIG. 4 schematically shows a block diagram of a dual-stage absorption chiller in accordance with a first embodiment of the invention. The first embodiment includes dual stages, identified as a high section 402 and a low section 404. Each stage includes a generator, an absorber, a heat exchanger, and a pump. The two stages of absorption/generation are designed for low-grade thermal sources. Low-grade thermal sources include heat energy that is available at relatively low temperatures. It is characterized by its lower potential to perform work efficiently, compared to high-grade thermal energy, which is available at higher temperatures. Low-grade thermal energy is abundant in various industries and natural processes but often remains underutilized due to challenges in its efficient conversion and utilization. A dual-stage of absorption chiller 132 may be driven by 60° C.-70° C. hot water, while a single-stage absorption chiller 200 may only be driven by the hot water above 80° C. Dual-stage absorption chillers 132 may use the low grade energy much better than the single stage absorption chillers 200.

A temperature difference between the ambient temperature and the heat source is not large enough for conventional single-stage absorption to generate enough driving pressure difference to start the refrigeration cycle. Single-stage absorption systems require an intermediate booster (heater), which introduces lower reliability, lower efficiency, higher complexity, and higher investment to the cooling system. The present invention may utilize dual-stage absorption and generation based on different solution concentrations. This beneficially generates higher pressure differences under certain heat source temperatures.

A low generator 460 and a high generator 481 may be supplied by the thermal storage tank 412 in parallel or in series. There is an optimal intermediate pressure for the best performance of the dual-stage absorption cycle. The intermediate pressure is floated between the high pressure and low pressure. But there exists the optimal intermediate pressure considering the best thermal performance of absorption chiller.

The temperature input from the data center 112 may be modulated for the best coefficient of performance (COP). The COP is a key performance metric used to evaluate the efficiency of heating, cooling, or refrigeration systems. It is defined as the ratio of useful thermal energy output (heating or cooling) to the energy input (usually electrical or mechanical energy) required to achieve that output.

The absorbing temperature at a low absorber 444 and a high absorber 466 have clear impacts on the refrigeration performance. By different flow patterns, the optimal working points may be achieved. Flow patterns refer to the way to organize the system configurations, for example two stage, three stage or single stage. Based on the different working conditions, the flow pattern may be selected accordingly and organize to achieve the best performance.

A concentrated solution in the low absorber 444 absorbs vapor from the evaporator 492 and creates low vapor pressure in a chamber of the evaporator 492 to maintain evaporation effects of the refrigerant by which the cooling capacity is created. After absorbing the refrigerant vapor, diluted solution is suctioned by pump 450, pumped through an internal heat exchanger 453, and heated. The hot diluted solution will proceed to the low generator 460 and be heated by the data center heat source from 420. Vapor generated at intermediate pressure will be suctioned in the high absorber 466. The concentrated solution in the low generator 460 will flow back to the internal heat exchanger 453.

The refrigerant vapor at the intermediate pressure will be absorbed by the refrigerant solution in the high absorber 466 and pumped to the high generator 481 through the internal heat exchanger 475. Intermediate pressure refers to the pressure between the high pressure and the low pressure. Here, it refers to the high pressure generated by the low stage and the low pressure of the high stage. When the solution is heated, the steam pressure above its surface increases, creating a high-pressure environment. The concentrated solution in the chamber of the high generator 481 will be heated by data center heat sources from 420. Vapor at high pressure will be released from the solution and condensed into liquid in the condenser chamber 487 by external cold fluid (e.g., water, PG25, etc.). The concentrated solution out of the high generator 481 will go back to the high absorber 466 after exchanging to complete a cycle.

The condensed liquid in the condenser 487 will be regulated by a valve 497 to a low-pressure level as a mixture of vapor and liquid 495, which then will be evaporated by the evaporator 492. When the high-pressure liquid passes through the throttling valve, the pressure drops to a low-pressure level. The evaporation will create the cooling effects to cool down the fluid in an evaporation coil of the evaporator 492.

The data center portion of FIG. 4 includes the data center cooling distribution system 112 (i.e., servers and associated cooling components/piping), a coolant supply line 406, and a coolant return line 408. The data center 112 serves as the heat source of the liquid cooling system and provides the heated coolant through the coolant supply line 406. Return coolant will flow back to the data center cooling distribution system 112 through the coolant return line 408.

The thermal storage tank portion of FIG. 4 includes a thermal storage tank 412, a coolant data center side inlet 414, a coolant data center side outlet 416, a coolant user side inlet 418, and a coolant user side outlet 420. The thermal storage tank 412 serves as a reservoir for the coolant. Heated coolant from the inlet 414 from the data center flows into the thermal storage tank 412 and the coolant will be maintained due to its large volume and flow out of the thermal storage tank 412 through the outlet 416. Meanwhile, the coolant through the inlet 418 flows into the thermal storage tank 412 and flows out through the outlet 420. The thermal storage tank 412 can maintain a stable supply temperature through the coolant user side outlet 420 due to its large volume.

In order to focus on the critical functions, some common knowledge and design/features have not been specifically discussed in the description, such as the circulation pump and various components for suctioning the fluid out of the outlet of the coolant-user side 420, driving the fluid through the inlet of hot fluid 482 and the outlet of hot fluid 483 in sequence, returning to the thermal storage tank 412 by the inlet of the coolant-user side 418; the circulation pump and components circulating the fluid between the liquid cooling system in the data center cooling distribution system 112 and the thermal storage tank 412; valves and components functioning as isolation, stop, drainage functions, etc. Although these components have not been specifically described, it should be understood the system requires the components to work properly.

The heat rejector portion of FIG. 4 includes a heat rejector to the ambient 430, an inlet of the coolant-chiller side 431, an outlet of the coolant-chiller side 432, an inlet of the coolant-ambient 433, and an outlet of the coolant-ambient 434. “Coolant-ambient” refers to the coolant at a near-ambient temperature. The heat rejector to ambient 430 may be considered as a cooling tower, a dry cooler, or other forms of heat rejection equipment. Heated coolant from the inlet of the coolant chiller side 431 will reject heat to the coolant from the inlet of the coolant-ambient 433 and it will be cooled down and flow out the outlet of the coolant-chiller side 432. Meanwhile, the heated coolant exit the heat rejector to ambient 430 through the outlet of the coolant-ambient 434. Coolant from the inlet of the coolant-ambient 433 can provide air for the dry cooler, a mixture of air and water for the cooling tower, humid air for an adiabatic cooler, and water for a closed loop cooling tower. Adiabatic coolers and closed-loop cooling towers are used to cool the coolant to nearly match the ambient temperature.

The low absorber section of FIG. 4 includes the low absorber 444, a cooling coolant inlet 445, a cooling coolant outlet 446, a solution inlet 447, a solution outlet 448, and a refrigerant inlet 449. Low-pressure vapor refrigerant from the refrigerant inlet 449 will be absorbed by the concentrated solution from the solution inlet 447. As a result, the concentrated solution will become the diluted solution and flow out of the low absorber 444 through the solution outlet 448. Because of absorption, pressure in the low absorber 444 will be maintained at the level of low pressure. Coolant from cooling coolant inlet 445 will extract the heat out of the low absorber 444 through the solution outlet 446.

The low solution pump section of FIG. 4 includes the low solution pump 450, a low solution pump inlet 451, and a low solution pump outlet 452. The low solution pump 450 pumps the diluted solution from the low absorber 444 to the low generator 460. The diluted solution is suctioned from the low solution pump inlet 451 and pushed through the low solution pump outlet 452.

The low heat exchanger section of FIG. 4 includes a low heat exchanger 453, a diluted solution inlet 454, a diluted solution outlet 455, a concentrated solution inlet 456, and a concentrated solution outlet 457. The low heat exchanger 453 is an internal heat exchanger that preheats the diluted solution through the diluted solution inlet 454 and precools the concentrated solution through the concentrated solution inlet 456. The preheated diluted solution from the diluted solution outlet 455 will be supplied to the low generator 460. The precooled concentrated solution out of the concentrated solution outlet 457 will be supplied to the low absorber 444.

The low generator section of FIG. 4 includes the low generator 460, a hot fluid inlet 461, a hot fluid outlet 462, a solution inlet 463, a solution outlet 464, and a refrigerant outlet 465. The heat source from the data center 112 passes through the hot fluid inlet 461 and hot fluid outlet 462 heats the diluted solution and generates the refrigerant vapor at an intermediate pressure (desorbing process). The intermediate pressure vapor refrigerant supplied through the refrigerant outlet 465 is generated by the desorbing process in the low generator 460. As a result, the diluted solution will be concentrated and flow out of the low generator 460 through the solution outlet 464. The diluted solution originates from the low absorber 444 and flows into the low generator 460 through the solution inlet 463. Because of desorbing, the pressure in the low generator 460 will be maintained at the intermediate pressure level.

The high absorber section of FIG. 4 includes the high absorber 466, the cooling coolant inlet 467, the cooling coolant outlet 468, the solution inlet 469, the solution outlet 470, and the refrigerant inlet 471. Intermediate-pressure vapor refrigerant from the refrigerant inlet 471 will be absorbed by the concentrated solution from the solution inlet 469. As a result, the concentrated solution will become the diluted solution and flow out of the high absorber 466 through the solution outlet 470. Because of absorption, the pressure in the high absorber 466 will be maintained at the intermediate pressure level. The coolant from the cooling coolant inlet 467 will bring the absorbing heat out of the high absorber 466 through the solution outlet 468.

The high solution pump section of FIG. 4 includes the high solution pump 472, a high solution pump inlet 473, and a high solution pump outlet 474. The high solution pump 472 pumps the diluted solution from the high absorber 466 to the high generator 481. The diluted solution is suctioned from the high pump inlet 473 and is pushed out through the high pump outlet 474.

The high heat exchanger section of FIG. 4 includes the high heat exchanger 475, a diluted solution inlet 476, a diluted solution outlet 477, a concentrated solution inlet 478, and a concentrated solution outlet 479. The high heat exchanger 475 is an internal heat exchanger that preheats the diluted solution through the diluted solution inlet 476 and precools the concentrated solution through the concentrated solution inlet 478. The preheated diluted solution from the diluted solution outlet 477 is supplied to the high generator 481. The precooled concentrated solution from the concentrated solution outlet 485 is supplied to the high absorber 466.

The high generator section of FIG. 4 includes the high generator 481, a hot fluid inlet 482, a hot fluid outlet 483, a refrigerant inlet 484, a refrigerant outlet 485, and a refrigerant outlet 486. The external heat source from the data center 420 enters the high generator 481 through the hot fluid inlet 482 and heats the diluted solution and generates the refrigerant vapor at high pressure to the hot fluid outlet 483, as the process of desorbing. The high-pressure vapor refrigerant supplied through the refrigerant outlet 486 is generated by the desorbing processes in the high generator 481. As a result, the diluted solution will be concentrated and then flow out of the high generator 481 through the solution outlet 485. The diluted solution originates from the high absorber 466 and flows into the high generator 481 through the solution inlet 484. Because of desorbing, the pressure in the high generator 481 will be maintained at a high pressure level. The high pressure level depends on the working fluid and operating conditions of the absorption chiller.

The condenser section of FIG. 4 includes the condenser 487, a cooling fluid inlet 488, a cooling fluid outlet 489, a refrigerant inlet 490, a refrigerant outlet 491, and a throttle valve 497. High-pressure vapor from the high generator 481 passes through the refrigerant inlet 490 and is condensed into liquid form by cold coolant through the cooling fluid inlet 488 and passes to the cooling fluid outlet 489. Condensed liquid flows out the condenser 487 through the refrigerant outlet 491. The liquid at high pressure is converted to low pressure by throttle valve 497, which is equivalent to the pressure level at the low absorber 444.

The evaporator section of FIG. 4 includes the evaporator 492, a cold fluid inlet 493, a cold fluid outlet 494, a refrigerant inlet 495, and a refrigerant outlet 496. A low-pressure mixture of vapor and liquid from the throttle valve 497 is supplied to the refrigerant inlet 495 of evaporator 492. Because of increased volume, evaporation absorbs the heat from the cold fluid through the cold fluid inlet 493 passing to the cold fluid outlet 494. Low pressure vapor is suctioned from the refrigerant outlet 496 into the low absorber 444 through the refrigerant inlet 449.

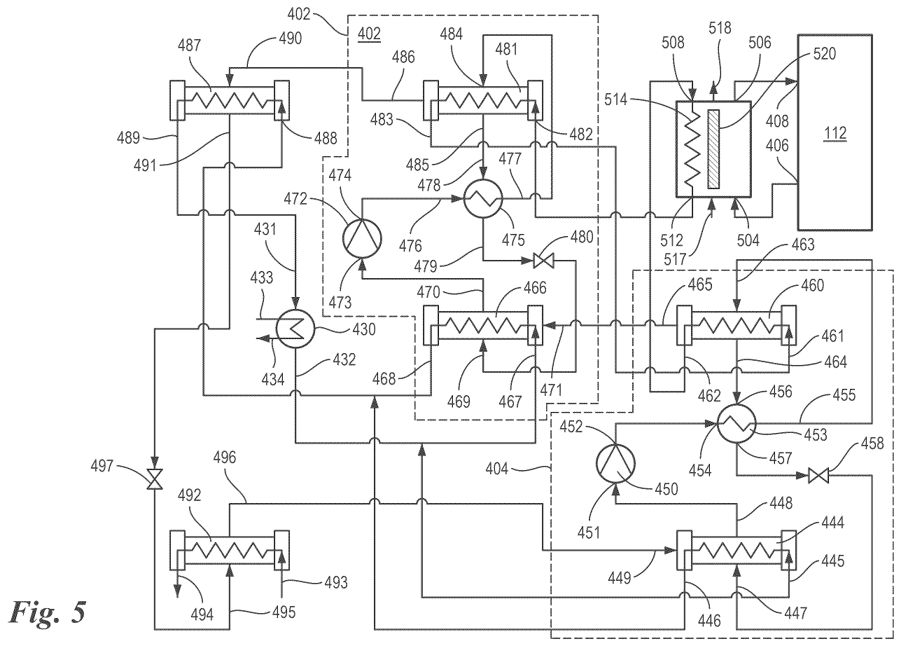

FIG. 5 schematically shows a block diagram of a dual-stage absorption chiller in accordance with a second embodiment of the invention. The embodiment illustrated includes a variant of the thermal storage tank 412 of FIG. 4.

As depicted in FIG. 4, the coolant supply from storage tank 412 to the high generator 481 and the low generator 460 is configured in a parallel configuration, by which the supply temperature to the hot fluid inlet 482 and the hot fluid inlet 461 are the same. By adjusting the opening of the high fluid valve 440 and the low fluid valve 442, the flow rate and heating capacity may be distributed between the high generator 481 and the low generator 460. A bypass valve of storage tank 424 will balance the flow when modulating the low fluid valve 442 and the high fluid valve 440.

Referring to FIG. 5, a heat exchanging coil 514 connects the coolant user side inlet 508 and the coolant user side outlet 512. As a result, the coolant at the data center side will be isolated from the user side coolant. For example, this may mitigate potential concerns about the water treatment in the system.

Phase change material may be inserted into the thermal storage tank 520 to improve its thermal storage capacity regarding the high latent heat of phase change materials. An additional hot water supply 518 may serve as the hot water supply port to the end user or heat exchanger for the purpose of heat reuse. An additional hot water return 517 provides the return line.

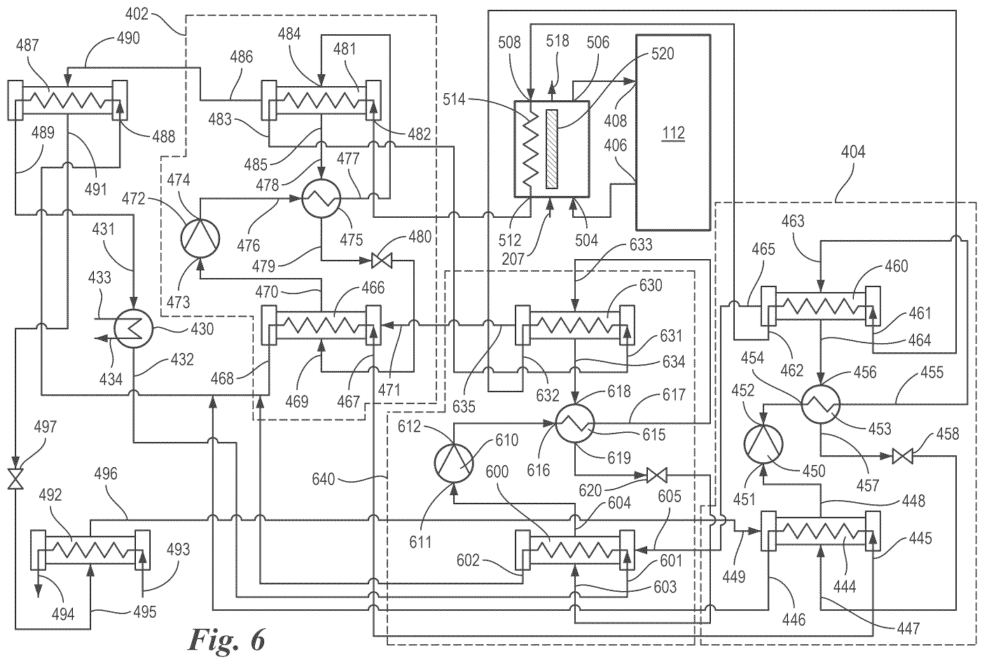

Referring to FIG. 6, a three stage absorption chiller system is shown. This has one additional stage over the systems shown in FIGS. 4 and 5. The purpose of the three-stage cycle is to lower the threshold of input fluid temperature, thereby widening the range of thermal energy to be reused. The three-stage absorption cycle system includes stage #1-absorber 444, pump 450, stage #1 heat exchanger 453, stage #1 generator 460, stage #2 absorber 600, stage #2 pump 610, stage #2 heat exchanger 615, stage #2 generator 630, stage #3 absorber 466, stage #3 pump 472, stage #3 pump 475, and stage #3 generator 481. The working pressure is elevated in a cascaded three-stage absorption system from stage #1 to stage #3. This cascading of pressure levels allows for a more effective utilization of the available heat energy, making the absorption refrigeration system more energy efficient. The same principle may be implemented in a four or five-stage absorption cycle which can use even low grade heat energy to drive circulation. However, the law of diminishing marginal returns applies to multiple-stage absorption systems, regarding thermodynamics limits.

The third embodiment includes a stage #1 absorber 444, a cooling coolant inlet 445, a cooling coolant outlet 446, a solution inlet 447, a solution outlet 448, a refrigerant inlet 449, a stage #1 pump 450, a low pump inlet 451, a low pump outlet 452, a stage #1 heat exchanger 453, a dilute solution inlet 454, a dilute solution outlet 455, a concentrated solution inlet 456, a concentrated solution outlet 457, a stage #1 generator 460, a hot fluid inlet 461, a hot fluid outlet 462, a solution inlet 463, a solution outlet 464, and a refrigerant outlet 465.

The low absorber 444 section of FIG. 6 includes the stage #1 absorber 444, the cooling coolant inlet 445, the cooling coolant outlet 446, the solution inlet 447, the solution outlet 448, and the refrigerant inlet 449. Low-pressure vapor refrigerant from refrigerant inlet 449 is absorbed by the concentrated solution from solution inlet 447. As a result, the concentrated solution will become the diluted solution and flow out of the low absorber 444 through the solution outlet 448. Because of absorption, pressure in the low absorber 444 is maintained at the low pressure level. Coolant from the cooling coolant inlet 445 will bring the absorbing heat out of the low absorber 444 through the solution outlet 446.

The low solution pump section of FIG. 6 includes the stage #1 pump 450, a pump inlet 451, and a pump outlet 452. The stage #1 solution pump 450 pumps the concentrated solution from the stage #1 absorber 444 to the stage #1 generator 460. The concentrated solution is suctioned from the stage #1 pump inlet 451 and is pushed out through the stage #1 pump outlet 452.

The low heat exchanger section of FIG. 6 includes the stage #1 heat exchanger 453, a dilute solution inlet 454, a dilute solution outlet 455, a concentrated solution inlet 456, and a concentrated solution outlet 457. The stage #1 heat exchanger 453 is an internal heat exchanger that preheats the diluted solution through the dilute solution inlet 454 and precools the concentrated solution through the concentrated solution inlet 456. The preheated diluted solution out of the dilute solution outlet 455 is supplied to the low generator 460. The precooled concentrated solution from the concentrated solution outlet 457 is supplied to the stage #1 absorber 444.

The stage #1 generator section of FIG. 6 includes stage #1 generator 460, a hot fluid inlet 461, a hot fluid outlet 462, a solution inlet 463, a solution outlet 464, and a refrigerant outlet 465. The external heat source from the data center passes through the hot fluid inlet 461 and hot fluid outlet 462 to heat the diluted solution and generate the refrigerant vapor at intermediate pressure, as the process of desorbing. The higher-pressure vapor refrigerant supplied through the refrigerant outlet 465 is generated by the desorbing processes in the stage #1 generator 460. As a result, the diluted solution will be concentrated and then flow out of the stage #1 generator 460 through the solution outlet 464. The diluted solution originates from stage #1 absorber 444 and flows into the stage #1 generator 460 through the solution inlet 463. Because of desorbing, the pressure in the stage #1 generator 460 will be maintained at the intermediate pressure level.

In an alternate embodiment to the system shown in FIG. 6, a three-stage absorption chiller may include a thermal tank 412 as shown in FIG. 4 in lieu of a heat exchanger 505-520 as shown in FIGS. 5 and 6.

The present application describes data center cooling systems having multiple and coordinated stages of cooling based on graduated pressure levels. Although detailed block diagrams and descriptions have been provided for cooling systems having dual stages (FIGS. 4 and 5) and three stages (FIG. 6), it should be understood that the present application covers any number of stages for data center cooling. However, as stated previously there may be diminishing returns with increasing stages since cost and complexity increase with each added stage and the added efficiency, while increasing, is progressively reduced for each additional stage. For example, four or more cooling stages may be undesirable in practical applications.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A multi-stage absorption chiller, comprising:
a plurality of absorber/generator stages, each stage configured to absorb cooled vapor with a concentrated solution to create a diluted solution, each stage configured to heat the diluted solution to produce a vapor refrigerant and the concentrated solution;
a condenser, configured to condense the vapor refrigerant to a cooled high pressure liquid;
a pressure regulator, configured to regulate the cooled high pressure liquid from the condenser to a low pressure mixture of liquid and vapor; and
an evaporator, configured to cool and evaporate the vapor from the low pressure mixture of liquid and vapor and provide the cooled vapor to the plurality of absorber/generator stages.

2. The multi-stage absorption chiller of claim 1, wherein the plurality of absorber/generator stages comprises:
a low absorber, configured to absorb a low pressure cooled vapor by a first concentrated solution to create a first diluted solution;
a low generator, configured to heat the first diluted solution from the low absorber to produce an intermediate pressure vapor refrigerant and the first concentrated solution to the low absorber;
a high absorber, configured to absorb the intermediate pressure vapor refrigerant from the low generator by a second concentrated solution to create a second diluted solution; and
a high generator, configured to heat the second diluted solution from the high absorber to produce a high pressure vapor refrigerant and the second concentrated solution to the high absorber.

3. The multi-stage absorption chiller of claim 2, wherein the plurality of absorber/generator stages further comprises:
an intermediate absorber, configured to absorb the intermediate pressure vapor refrigerant from the low generator by a second concentrated solution to create a second diluted solution; and
an intermediate generator, configured to heat the second diluted solution from the intermediate absorber to produce a high pressure vapor refrigerant and the second concentrated solution to the intermediate absorber,
wherein the high absorber is instead configured to absorb the high pressure vapor refrigerant from the intermediate generator by a third concentrated solution to create a third diluted solution; and
wherein the high generator is instead configured to heat the third diluted solution from the high absorber to produce a high pressure vapor refrigerant and the third concentrated solution to the high absorber.

4. The multi-stage absorption chiller of claim 2, wherein the low generator and the high generator heat the first diluted solution and the second diluted solution, respectively, from a heated concentrated coolant from a data center and supply cooled concentrated coolant to the data center.

5. The multi-stage absorption chiller of claim 2, comprising:
a low pump, configured to pump the first diluted solution from the low absorber to the low generator; and
a high pump, configured to pump the second diluted solution from the high absorber to the high generator.

6. The multi-stage absorption chiller of claim 2, comprising:
a low heat exchanger, configured to transfer heat from the first concentrated solution to the first diluted solution; and
a high heat exchanger, configured to transfer heat from the second concentrated solution to the second diluted solution.

7. The multi-stage absorption chiller of claim 1, comprising:
a heat rejector, configured to cool the cooling fluid from the condenser and provide cooled cooling fluid to at least a low absorber and a high absorber of the plurality of absorber/generator stages, wherein at least the low absorber and the high absorber are configured to supply heated cooling fluid to the condenser.

8. The multi-stage absorption chiller of claim 1, wherein the intermediate temperature tracks the high temperature.

9. A system, comprising:
a primary cooling loop, comprising:
a multi-stage absorption chiller, configured to receive a heated primary loop coolant from a primary side of a data center heat exchanger and supply a cooled primary loop coolant to the primary side of the data center heat exchanger, the multi-stage absorption chiller comprising:
a plurality of absorber/generator stages, each stage configured to absorb cooled vapor by a concentrated solution to create a diluted solution and heat the diluted solution to produce a vapor refrigerant and the concentrated solution;
a condenser, configured to condense the vapor refrigerant to a cooled high pressure liquid;
a pressure regulator, configured to regulate the cooled high pressure liquid from the condenser to a low pressure mixture of liquid and vapor;
an evaporator, configured to cool and evaporate the vapor from the low pressure mixture of liquid and vapor and provide the cooled vapor to the plurality of absorber/generator stages; and
a condenser, configured to condense the high pressure vapor refrigerant from the high generator to a cooled high pressure liquid; and
a secondary cooling loop, comprising:
one or more server racks of a data center, configured to receive a cooled data center coolant from a secondary side of the data center heat exchanger and supply a heated data center coolant to the secondary side of the data center heat exchanger.

10. The system of claim 9, comprising:
a distribution system, coupled to the multi-stage absorption chiller, configured to provide cooled refrigerant to one or more of commercial cooling, cooling external to the data center, and air conditioning for the data center.

11. The system of claim 9, comprising:
a heat exchanging coil, configured to isolate the primary cooling loop from the secondary cooling loop, wherein the secondary cooling loop exchanges a heated concentrated coolant with a cooled concentrated coolant.

12. The system of claim 9, comprising:
a thermal storage tank, comprising phase change material, wherein the thermal storage tank receives a heated concentrated coolant and provides a cooled concentrated coolant, wherein the phase change material improves a thermal storage capacity of the thermal storage tank due to high latent heat of the phase change material.

13. The system of claim 9, wherein the plurality of absorber/generator stages comprises:
a low absorber, configured to absorb a low pressure cooled vapor by a first concentrated solution to create a first diluted solution;
a low generator, configured to heat the first diluted solution from the low absorber to produce an intermediate pressure vapor refrigerant and the first concentrated solution to the low absorber;
a high absorber, configured to absorb the intermediate pressure vapor refrigerant from the low generator by a second concentrated solution to create a second diluted solution; and
a high generator, configured to heat the second diluted solution from the high absorber to produce a high pressure vapor refrigerant and the second concentrated solution to the high absorber.

14. The system of claim 13, wherein the low generator and the high generator are configured to heat the first diluted solution and the second diluted solution, respectively, from a heated concentrated coolant from the data center and supply a cooled concentrated coolant to the data center.

15. The system of claim 13, comprising:
a low pump, configured to pump the first diluted solution from the low absorber to the low generator; and
a high pump, configured to pump the second diluted solution from the high absorber to the high generator.

16. The system of claim 13, comprising:
a low heat exchanger, configured to transfer heat from the first concentrated solution to the first diluted solution; and
a high heat exchanger, configured to transfer heat from the second concentrated solution to the second diluted solution.

17. The system of claim 13, comprising:
a heat rejector, configured to cool the cooling fluid from the condenser and provide cooled cooling fluid to the low absorber and the high absorber, wherein the low absorber and the high absorber are configured to supply heated cooling fluid to the condenser.

18. The system of claim 13, wherein one or more of a heat exchanger coil or a thermal storage tank provides heated concentrated coolant from the data center through the high generator, through the low generator, and return cooled concentrated coolant to the data center in a series configuration.

19. A three-stage absorption chiller, comprising:
a low absorber, configured to absorb low pressure cooled vapor by a first concentrated solution to create a first diluted solution;
a low generator, configured to heat the first diluted solution from the low absorber to produce an intermediate pressure refrigerated vapor and the first concentrated solution to the low absorber;
an intermediate absorber, configured to absorb intermediate pressure cooled vapor by a second concentrated solution to create a second diluted solution;
an intermediate generator, configured to heat the second diluted solution from the intermediate absorber to produce a high pressure refrigerated vapor and the second concentrated solution to the intermediate absorber;
a high absorber, configured to absorb the high pressure refrigerated vapor from the intermediate generator by a third concentrated solution to create a third diluted solution;
a high generator, configured to heat the third diluted solution from the high absorber to produce a high pressure vapor refrigerant and the third concentrated solution to the high absorber;
a condenser, configured to condense the high pressure vapor refrigerant from the high generator to a cooled high pressure liquid;
a pressure regulator, configured to regulate the cooled high pressure liquid from the condenser to a low pressure mixture of liquid and vapor; and
an evaporator, configured to cool and evaporate the vapor from the low pressure mixture of liquid and vapor and provide the low pressure cooled vapor to the low absorber.

20. The three-stage absorption chiller of claim 19, comprising:
a low pump, configured to pump the first diluted solution from the low absorber to the low generator;
an intermediate pump, configured to pump the second diluted solution from the intermediate absorber to the intermediate generator; and
a high pump, configured to pump the third diluted solution from the high absorber to the high generator.

21. The three-stage absorption chiller of claim 20, comprising:
a low heat exchanger, configured to transfer heat from the first concentrated solution to the first diluted solution;
an intermediate heat exchanger, configured to transfer heat from the second concentrated solution to the second diluted solution; and
a high heat exchanger, configured to transfer heat from the second concentrated solution to the second diluted solution.
